(19) United States
(12) Patent Application Publication
(10) Pub. No.: US 2014/0170519 A1
(43) Pub. Date: Jun. 19, 2014

(54) Flow Battery System and Method Thereof

(71) Applicants: BOSCH ENERGY STORAGE SOLUTIONS LLC, Farmington Hills, MI (US); ROBERT BOSCH GMBH, Stuttgart (DE)

(72) Inventors: Maksim Subbotin, Menlo Park, CA (US); Ashish Krupadanam, Cupertino, CA (US); Nalin Chaturvedi, Sunnyvale, CA (US)

(73) Assignees: ROBERT BOSCH GMBH, Stuttgart (DE); BOSCH ENERGY STORAGE SOLUTIONS LLC, Farmington Hills, MI (US)

(21) Appl. No.: 13/720,661

(22) Filed: Dec. 19, 2012

(51) Int. Cl. H01M 8/04; H01M 8/20; G01R 31/36; H01M 8/18

(52) U.S. Cl. CPC H01M 8/04276; H01M 8/188; H01M 8/20; G01R 31/3606
USPC 429/451; 702/63

(57) ABSTRACT

A redox flow battery system includes a first flow compartment, a second flow compartment, an ion exchange membrane positioned between the first flow compartment and the second flow compartment, a first pump configured to pump a first half-cell electrolyte from a first storage tank to the first flow compartment, a second pump configured to pump a second half-cell electrolyte from a second storage tank to the second flow compartment, a first weight sensor configured to provide a first weight signal associated with the weight of the first storage tank and the first half-cell electrolyte within the first storage tank, a memory in which command instructions are stored, and a processor configured to execute the command instructions to obtain the first weight signal, and to control the first pump, current and voltage on terminals of flow battery based upon the obtained first weight signal.

### FIELD

This disclosure relates to batteries, and more particularly, to flow battery system and method thereof.

### BACKGROUND

A flow battery is a form of rechargeable battery in which electrolyte containing one or more dissolved electro-active species flows through an electrochemical cell that converts chemical energy directly to electricity. The electrolyte is stored externally, generally in tanks, and is pumped through the cell (or cells) of the reactor. Due to the fact that conversion takes place in the cell of the battery, while the electrolyte with the active species is stored in individual tank or tanks, flow battery systems allow separation between power that can be provided or absorbed by the battery and the amount of energy that can be stored. Power is defined by the properties and the dimensions of the cell, while the amount of energy is defined by capacity of the tanks storing the active ingredients.

Flow batteries are a promising technology for storage of electrical energy in stationary applications such as grid-scale renewable bulk energy storage systems, rail regeneration storage systems, and grid-scale frequency regulation systems. These applications require large storage capacities and hence only cost-effective technologies are considered as sustainable long-term solutions.

Because large scale storage systems are stationary, restrictions on dimensions and weight are less strenuous than for mobile systems. Efficiency requirements are also less strict than those for mobile applications since in most situations the stationary systems provide storage for electrical energy which otherwise would be dissipated (in the case of rail regeneration), not generated due to the lack of load in off-peak hours (in the case with wind and solar) or generated with low-efficiency sources such as oil or gas peaker plants (in the case of frequency and peak regulation).

Control of flow batteries requires knowledge of the flow rate and State of Charge (SOC). Together, flow rate and SOC determine the concentration and availability of reactants at the electrodes and the current that can be drawn from the cell for the best efficiency and within safe limits. The SOC is thus used to determine how much energy the battery can store or deliver. This can be used to plan the usage of the battery in a device or within a power supply system. It may also determine the power that the battery can produce.

Estimation of SOC of electro-chemical batteries including flow batteries is considered as one of the most challenging and important technical problems that has to be solved in order to guarantee efficient and reliable operation of an energy storage system. Accurate estimation of SOC of a battery is required for evaluation of the amount of energy that is stored in the battery or can be accumulated by the battery. More importantly SOC is required for correct definition of charge and discharge parameters of the battery such as electric currents and voltages that can be applied to and expected from the battery. These parameters define safe operation margins for the battery and affect its instantaneous and long-term performance and its life span. Accurate estimation of SOC allows optimal operation of a given electrochemical battery and, as a result, provides the most efficient technical and economical utilization of individual battery cells and combined battery systems.

A need exists for a flow battery system which allows for simple and accurate SOC determination. A further need exists for a flow battery system which can easily provide SOC determination without the need for additional penetrations into the fluid system of the flow battery.

### SUMMARY

A redox flow battery system includes a first flow compartment, a second flow compartment, an ion exchange membrane positioned between the first flow compartment and the second flow compartment, a first pump configured to pump a first half-cell electrolyte from a first storage tank to the first flow compartment, a second pump configured to pump a second half-cell electrolyte from a second storage tank to the second flow compartment, a first weight sensor configured to provide a first weight signal associated with the weight of the first storage tank and the first half-cell electrolyte within the first storage tank, a memory in which command instructions are stored, and a processor configured to execute the command instructions to obtain the first weight signal, and to control the first pump, current and voltage on the terminals of electrochemical cell based upon the obtained first weight signal.

In another embodiment, a redox flow battery system includes a reactor including a first flow compartment, a second flow compartment, and an ion exchange membrane positioned between the first flow compartment and the second flow compartment, a first pump configured to pump a first half-cell electrolyte from a first storage tank to the first flow compartment, a second pump configured to pump a second half-cell electrolyte from a second storage tank to the second flow compartment, a first weight sensor configured to provide a first weight signal associated with the weight of the reactor, a memory in which command instructions are stored, and a processor configured to execute the command instructions to obtain the first weight signal, and to determine a state of charge of the system based upon the obtained first weight signal.

In another embodiment, a method of controlling a flow battery system includes storing data indicative of the relationship between a range of weights of a reactor including a first and a second flow compartment, and a range of states of charge for the flow battery system in a memory, generating a signal associated with the weight of the cell component, receiving the signal associated with the weight of the cell component, and identifying a state of charge of the flow battery system based upon the received signal and the stored data.

### BRIEF DESCRIPTION OF THE DRAWINGS

FIG. 1 depicts a schematic of a flow battery system in accordance with principles of the present invention;

FIG. 2 depicts a schematic of the control system of the flow battery system of FIG. 1;

FIG. 3 depicts a graphical representation of the relationship between the weight of a reactor and the SOC of the flow battery system of FIG. 1;

FIG. 4 depicts a graphical representation of the relationship between the weight of an electrolyte tank and the SOC of the flow battery system of FIG. 1; and

FIG. 5 depicts a process controlled by the control system of FIG. 2 which is various embodiments is used to determine the SOC of the flow battery system of FIG. 1 and/or to control one or more of the pumps in the system of FIG. 1 and current and voltage on the terminals of the reactor.

### DESCRIPTION

For the purposes of promoting an understanding of the principles of the invention, reference will now be made to the embodiments illustrated in the drawings and described in the following written specification. It is understood that no limitation to the scope of the invention is thereby intended. It is further understood that the present invention includes any alterations and modifications to the illustrated embodiments and includes further applications of the principles of the invention as would normally occur to one skilled in the art to which this invention pertains.

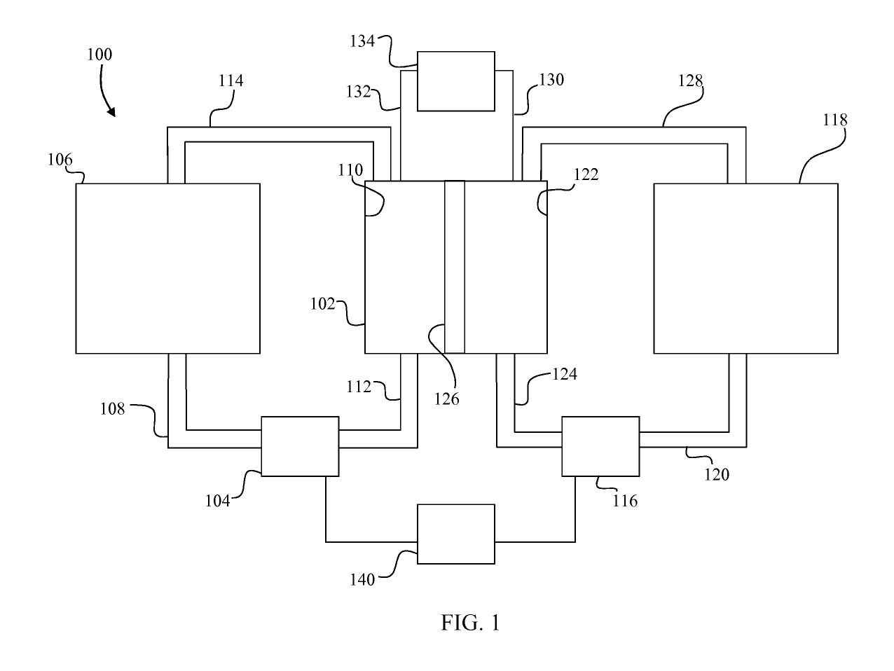

FIG. 1 depicts a flow battery system 100 which includes a reactor 102. A pump 104 takes suction from an electrolyte tank 106 though a supply line 108. The pump 104 provides a first half-cell electrolyte to a first flow compartment 110 of the reactor 102 through a feed line 112. The first half-cell electrolyte is returned to the electrolyte tank 106 from the reactor 102 through a return line 114.

A pump 116 takes suction from a second electrolyte tank 118 though a supply line 120. The pump 116 provides a second half-cell electrolyte to a second flow compartment 122 of the reactor 102 through a feed line 124. The flow compartment 122 is separated from the flow compartment 110 by an ion exchange membrane 126. The second half-cell electrolyte is returned to the electrolyte tank 118 from the reactor 102 through a return line 128.

Within the reactor 102, the first half-cell electrolyte and the second half-cell electrolyte chemically react through the ion exchange membrane 126 similar to a hydrogen fuel cell or an electrolyser generating a positive charge at a first electrode 130 and a negative charge at a second electrode 132. The first half-cell electrolyte in one embodiment is a negative half-cell electrolyte while the second half-cell electrolyte is a positive half-cell electrolyte. The electrodes 130 and 132 may be connected to a load 134 to power the load 134.

Operation of the feed pumps 104 and 116, and thus the generation of charge on the electrodes 130 and 132, is controlled by a control system 140. The control system 140 is operably connected to the pumps 104 and 116 to control operation of pumps 104 and 116.

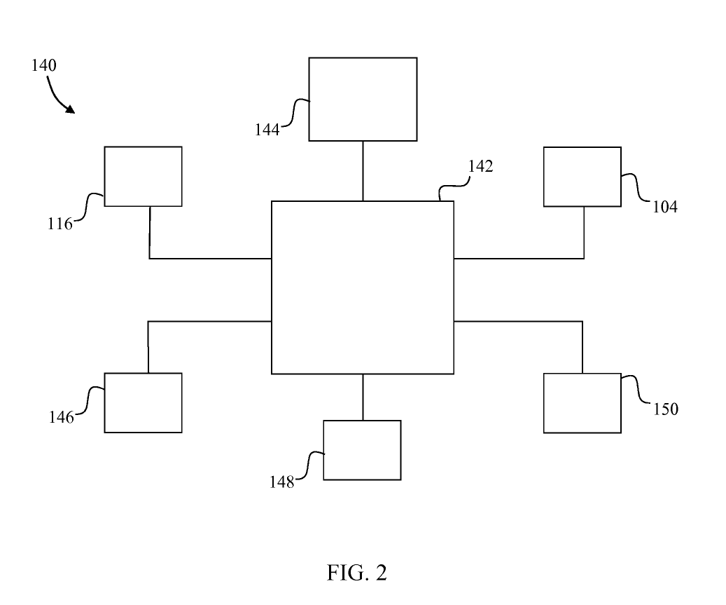

The control system 140, shown in more detail in FIG. 2, includes a processor 142 and a memory 144 in which command instructions are stored. The processor 142 is operably connected to the pumps 104 and 116. The processor 142 is further operably connected to weight sensors 146, 148, and 150.

The weight sensors 146, 148, and 150 are, in various embodiments, load cells and strain gages. The weight sensors 146, 148, and 150 in one embodiment are placed directly under the electrolyte tanks 106 and 118, and the reactor 102, respectively. For example, the weight sensor 146, in one embodiment, is placed directly under the electrolyte tank 106 and configured to measure the weight of the electrolyte tank 106 including all of the half-cell electrolyte within the electrolyte tank 106. In some embodiments, one or more of the weight sensors 146, 148, and 150 are integrated into component attachment elements. In other embodiments, one or more of the weight sensors 146, 148, and 150, are integrated into a suspension system of the associated component.

The control system 140 is configured to determine the state of charge (SOC) of the system 100 using inputs from one or more of the weight sensors 146, 148, and 150. In some embodiments, the control system 140 is configured to control one or more of the pumps 104 and 116, and current and voltage on the terminals 132, 130 of the reactor using inputs from one or more of the weight sensors 146, 148, and 150, either in addition to determining the SOC of the system 100 or as an alternative to determining the SOC of the system 100.

The SOC of the system 100 is related to the weight of different components in the system 100 because concentrations of active chemical species stored in the half-cell electrolytes change as the system 100 undergoes charge or discharge. During charge or discharge processes the active species react in the reactor 102 and are extracted from or introduced back into the half-cell electrolyte solution. Depending on the selected architecture of the system 100, the active species can be concentrated within the reactor 102 or within the half-cell electrolyte. As a consequence of these electrochemical reactions, the weights of the electrolyte tanks 106 and 118, as well as the weight of the reactor 102 change. Measurement of changes in weights of the reactor 102 and/or one or more of the electrolyte tanks 106 and 118 (which includes the weight of the half-cell electrolyte and active material within the respective components) provide a reliable method for estimation of the amount of active chemical species remaining in the half-cell electrolyte. Consequently, the output characteristics of the system 100 can be controlled by controlling the pumps 104 and 116 and current and voltage on the terminals of the reactor. Moreover, SOC of the system 100 is a function of the amount of species reacted during charge-discharge process and hence the change in weight of its components. Therefore, by obtaining a weight of one or more components of the system 100, the SOC of the system can be determined once the relationship between the weight of the component and SOC of the system 100 is mapped.

SOC of the system 100 is mapped by experimentally measuring the function, SOC=f(weight change), for one or more of the reactor 102, the electrolyte tank 106, and the electrolyte tank 118. In one embodiment, this data is obtained by recording the change in weight versus SOC as measured in Ah or Wh.

By way of example, FIG. 3 depicts an exemplary relationship between SOC and weight of the reactor 102 where the active chemical species are deposited within the reactor 102 during a charge process. Chart 160 of FIG. 3 indicates that when the system 100 has a low SOC (SOC1), the mass of the reactor 102 is low (m1). As the system 100 charges, active material is deposited within the reactor 102. Accordingly, while the weight of the half-cell electrolytes within the reactor 102 decreases (active material is removed from the half-cell electrolytes), the overall weight of the reactor 102 increases such that at a higher SOC (SOC2), the mass of the reactor 102 has increased (m2). By obtaining data throughout a SOC region of interest, the relationship (curve 162) between the weight of the reactor 102 and the SOC of the system 100 is obtained.

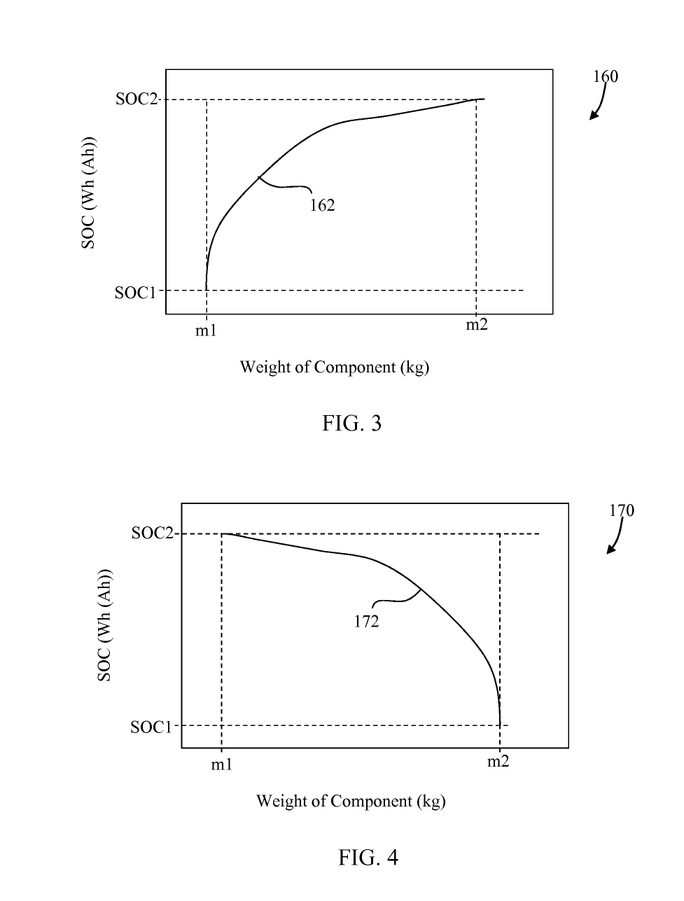

As noted above, the relationship between SOC and the weight of one or more of the electrolyte tanks 106/118 may also or alternatively be determined. By way of example, chart 170 of FIG. 4 indicates that when the system 100 has a low SOC (SOC1), the mass of the electrolyte tank 106 is high (m2). As the system 100 charges, active material is deposited within the reactor 102. Accordingly, the weight of the half-cell electrolytes within the electrolyte tank 106 decreases (active material is removed from the half-cell electrolytes). Thus, the overall weight of the electrolyte tank 106 decreases such that at a higher SOC (SOC2), the mass of the electrolyte tank 106 has decreased (m1). By obtaining data throughout a SOC region of interest, the relationship (curve 172) between the weight of the electrolyte tank 106 and the SOC of the system 100 is obtained.

As noted above, in some embodiments, the relationship between the electrolyte tank 118 and the SOC of the system 100 is also obtained. While only two electrolyte tanks 106 and 118 are depicted in the embodiment of FIG. 1, in some embodiments additional tanks are provided and characterized in the above manner.

In some embodiments, the weight of the electrolyte tanks may further change because of changes in the volume of electrolyte within the tanks during system operation. In these embodiments, the corresponding corrections for changes in weight due to volume are also characterized.

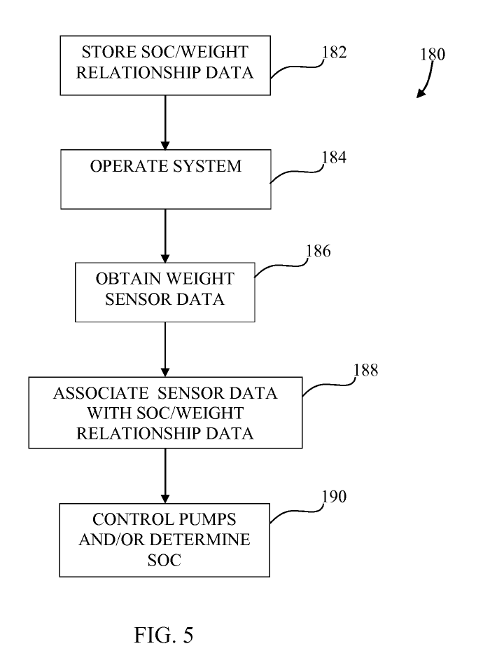

In one embodiment, the processor 142 executes command instructions stored within the memory 144 in accordance with a procedure 180 of FIG. 5 to determining the SOC of the system 100. Initially, data associated with the relationship between the SOC of the system 100 and the weight of one or more of the reactor 102, the electrolyte tank 106, and the electrolyte tank 118 are stored in the memory 144 at block 182. The system 100 is then operated (block 184). During operation, the processor 142 obtains weight data from one or more of the weight sensors 146, 148 and 150 (block 186). At block 188, the processor 142 associates the obtained weight data with stored SOC/weight relationship data.

The processor 142 then controls one or more of the pumps 104/116 and current and voltage on the terminals of the reactor based upon the correlated SOC/weight relationship data to provide desired operational characteristics for the system 100. In one embodiment, the processor 142 simply controls one or more of the pumps 104/116 to provide a desired output current. In another embodiment, the processor 142 identifies a present SOC for the system 100. The identified SOC data may be stored in the memory 144 for future use or provided as a system output on an output device (not shown). In some embodiments, all of the above functions are provided.

As described above, once the SOC of the system 100 as a function of the weight of one or more components in the system 100 is determined, one can reliably map measured weight of the components to the SOC of the system 100. The weight measurements can be performed continuously in time, periodically with a certain time interval, or only at the beginning and the end of a charge or discharge cycle depending on the requirements from the battery management and control system.

The disclosed system and method are robust to inaccuracies due to absolute measurement errors since they utilize the difference between the weight measurements and do not depend on the absolute values of the measurements. As a consequence, any errors in absolute values of initial weight measurements of the corresponding components are irrelevant to the final estimate of SOC. For example, with respect to the curve 162 depicted in FIG. 3, the absolute position of the initial weight (m1) of the component along the x-axis does not influence the accuracy of the SOC estimate. This is a significant consideration since widely available weight measurement devices often provide much more accurate relative measurements compared to absolute measurements.

Sensitivity of the above described system and method depends on the accuracy of the weight sensors which in various embodiments are load cells or strain gages as well as the ratio between the weights of a given component of the battery in the charged and the discharged state. A higher ratio between charged and discharged weights (“weight ratio”) results in higher weight measurement sensitivity and hence can provide more accurate estimates of SOC. Since typical designs of flow batteries utilize high density heavy active ingredients such as zinc, iron, vanadium or lead, change in weight of a given battery component defined by the amount of the active ingredient deposited in the reactor 102 or extracted from electrolyte is generally significant. Thus, high weight ratios are readily obtained.

While certain operations were detailed above in describing operation of the system 100, various modifications to the process 180 may be incorporated in various embodiments. For example, the properties of electrolyte and performance of the reactor 102 will change over time due to variations in operating conditions, and aging of system components. Additionally, from system to system there will be variations of performance due to imperfections of manufacturing process. Accordingly, some embodiments include an adaptive algorithm that monitors and adjusts the initial experimentally or analytically defined mapping stored within the memory 144 (e.g. at block 182). The mapping in some embodiments is adapted utilizing measurements of the true SOC of the battery performed with external devices at the beginning and the end of a charge and discharge cycle. The adaptation in some embodiments is performed by adjustment of the available map such that SOC calculated with the map from the measured weight is equal to the SOC measured with external devices at certain check points. For example, one of the check points may be a completely discharged state when it is known that the active ingredient is completely dissolved in electrolyte and SOC=0.

Moreover, while the above described embodiment includes an ion membrane and two separate electrolyte storage tanks, each tank dedicated to a single half-cell electrolyte, some embodiments do not include an ion membrane separating the two electrolytes. In these embodiments, a single electrolyte mixture including two half-cell electrolytes is circulated by one or more pumps. The single electrolyte mixture is separated during charge process into high density and low density fluids that in some embodiments are stored in one tank.

While the invention has been illustrated and described in detail in the drawings and foregoing description, the same should be considered as illustrative and not restrictive in character. It is understood that only the preferred embodiments have been presented and that all changes, modifications and further applications that come within the spirit of the invention are desired to be protected.

1. A redox flow battery system, comprising:
a first flow compartment;
a second flow compartment;
an ion exchange membrane positioned between the first flow compartment and the second flow compartment;
a first pump configured to pump a first half-cell electrolyte from a first storage tank to the first flow compartment;
a second pump configured to pump a second half-cell electrolyte from a second storage tank to the second flow compartment;
a first weight sensor configured to provide a first weight signal associated with the weight of the first storage tank and the first half-cell electrolyte within the first storage tank;
a memory in which command instructions are stored; and
a processor configured to execute the command instructions to obtain the first weight signal, and to control the first pump and a current and a voltage of the battery system based upon the obtained first weight signal.

2. The system of claim 1, further comprising:
a second weight sensor configured to provide a second weight signal associated with the weight of the second storage tank and the second half-cell electrolyte within the second storage tank, wherein the processor is further configured to execute the command instructions to obtain the second weight signal, and to control the second pump and the current and the voltage of the system based upon the obtained second weight signal.

3. The system of claim 1, wherein the processor is further configured to execute the command instructions to associate the obtained first weight signal with a state of charge of the system.

4. The system of claim 3, further comprising:
a second weight sensor configured to provide a second weight signal associated with the weight of the second storage tank and the second half-cell electrolyte within the second storage tank, wherein the processor is further configured to execute the command instructions to obtain the second weight signal, and to identify the state of charge of the system based upon the obtained second weight signal.

5. The system of claim 3, wherein the first flow compartment, the second flow compartment, and the ion exchange membrane are contained within a reactor, the system further comprising:
a second weight sensor configured to provide a second weight signal associated with the weight of the reactor and the first flow compartment, the second flow compartment, and the ion exchange membrane within the cell housing, wherein the processor is further configured to execute the command instructions to obtain the second weight signal, and to identify the state of charge of the system based upon the obtained second weight signal.

6. The system of claim 1, wherein the first half-cell electrolyte is a negative half-cell electrolyte.

7. A redox flow battery system, comprising:
a reactor;
at least one pump configured to pump a first half-cell electrolyte and a second half-cell electrolyte from at least one storage tank to the reactor;
a first weight sensor configured to provide a first weight signal associated with the weight of the reactor and the first half-cell electrolyte and the second half-cell electrolyte within the reactor;
a memory in which command instructions are stored; and
a processor configured to execute the command instructions to obtain the first weight signal, and to determine a state of charge of the system based upon the obtained first weight signal.

8. The system of claim 7, further comprising:
at least one second weight sensor configured to provide at least one second weight signal associated with the weight of the at least one storage tank and any of the first half-cell electrolyte and any of the second half-cell electrolyte within the at least one storage tank, wherein the processor is further configured to execute the command instructions to obtain the at least one second weight signal, and to determine the state of charge of the system based upon the obtained at least one second weight signal.

9. The system of claim 7, wherein the processor is further configured to execute the command instructions to control the at least one pump, and the current and the voltage of the battery system based upon the obtained first weight signal.

10. The system of claim 9, wherein:
the at least one storage tank comprises a first storage tank configured to store the first half-cell electrolyte; and
the at least one storage tank comprises a second storage tank configured to store the second half-cell electrolyte, the system further comprising:
a second weight sensor configured to provide a second weight signal associated with the weight of the second storage tank and the second half-cell electrolyte within the second storage tank, wherein the processor is further configured to execute the command instructions to obtain the second weight signal, and to determine the state of charge of the system based upon the obtained second weight signal.

11. The system of claim 10, wherein the second half-cell electrolyte is a negative half-cell electrolyte.

12. A method of controlling a flow battery system, comprising:
storing first data indicative of the relationship between a range of weights of a reactor including a first and a second flow compartment, and a range of states of charge for the flow battery system in a memory;
generating a first signal associated with the weight of the cell component;
receiving the first signal associated with the weight of the cell component; and
identifying a state of charge of the flow battery system based upon the received first signal and the stored first data.

13. The method of claim 12, further comprising:
controlling a first flow pump based upon the identified state of charge.

14. The method of claim 12, further comprising:
controlling current and voltage on terminals of the battery system based upon the identified state of charge.

15. The method of claim 12, further comprising:
storing second data indicative of the relationship between a range of weights of a first electrolyte tank and a range of states of charge for the flow battery system in the memory;
generating a second signal associated with the weight of the first electrolyte tank;
receiving the second signal associated with the weight of the first electrolyte tank; and
identifying the state of charge of the flow battery system based upon the received second signal and the stored second data.

16. The method of claim 15, further comprising:
controlling a first flow pump based upon the identified state of charge.

17. The method of claim 15, further comprising:
controlling current and voltage on terminals of the reactor based upon the identified state of charge.

18. The method of claim 15, further comprising:
storing third data indicative of the relationship between a range of weights of a second electrolyte tank and a range of states of charge for the flow battery system in the memory;
generating a third signal associated with the weight of the first electrolyte tank;
receiving the third signal associated with the weight of the first electrolyte tank; and
identifying the state of charge of the flow battery system based upon the received third signal and the stored third data.

19. The method of claim 18, further comprising:
controlling a first flow pump based upon the identified state of charge.

20. The method of claim 19, further comprising:
controlling a second flow pump based upon the identified state of charge.
